(19) United States
(12) Patent Application Publication
(10) Pub. No.: US 2019/0273004 A1
(43) Pub. Date: Sep. 5, 2019

(54) VACUUM PROCESSING APPARATUS AND EXHAUST CONTROL METHOD

(71) Applicant: Tokyo Electron Limited, Tokyo (JP)

(72) Inventor: Takehiro Ueda, Miyagi (JP)

(21) Appl. No.: 16/285,482

(22) Filed: Feb. 26, 2019

(30) Foreign Application Priority Data
Mar. 2, 2018 (JP) 2018-037584

(51) Int. Cl. H01L 21/67; H01J 37/32; H01J 37/18

(52) U.S. Cl. CPC H01L 21/67069; H01J 37/32449; H01J 37/18; H01J 37/32027; H01J 37/32834

(57) ABSTRACT

A processing container includes a processing container including a placement table configured to place a workpiece thereon and a gas supply source configured to supply a processing gas; a plurality of exhaust mechanisms provided around the placement table and configured to control an exhaust amount of the processing gas; a plurality of sensors configured to detect pressure at a plurality of positions distributed within the processing container; and a controller configured to control exhaust amounts of the plurality of exhaust mechanisms based on a result of pressure detection by the plurality of sensors so as to suppress unevenness in a pressure of the processing gas supplied to the workpiece.

### CROSS-REFERENCE TO RELATED APPLICATIONS

This application is based on and claims priority from Japanese Patent Application No. 2018-037584, filed on Mar. 2, 2018, with the Japan Patent Office, the disclosures of which are incorporated herein in their entireties by reference.

### TECHNICAL FIELD

The present disclosure relates to a vacuum processing apparatus and an exhaust control method.

### BACKGROUND

In the related art, there has been known a vacuum processing apparatus in which a workpiece is disposed in a processing container having a predetermined vacuum degree and a processing gas is supplied to perform a predetermined processing on the workpiece. As an example of a vacuum processing apparatus, for example, a plasma etching apparatus may be mentioned. In the plasma etching apparatus, a substrate such as a semiconductor wafer (hereinafter referred to as a “wafer”) is disposed as a workpiece in a processing container having a predetermined vacuum degree, a processing gas is supplied so as to generate plasma, and an etching processing is performed.

In the vacuum processing apparatus, exhaust mechanisms which evacuate the interior of the processing chamber may be arranged unevenly. For example, in the etching processing, in order to generate plasma, radio-frequency power is supplied to a placement table on which a substrate is mounted. Therefore, in the plasma etching apparatus, components such as, for example, a radio-frequency power supply, are disposed under the placement table, and exhaust mechanisms are arranged unevenly around the placement table. See, for example, Japanese Patent Laid-open Publication Nos. 2014-090022 and 2012-195569.

### SUMMARY

A vacuum processing apparatus according to an aspect of the present disclosure includes: a processing container including a placement table configured to place a workpiece thereon and a gas supply source configured to supply a processing gas; a plurality of exhaust mechanisms each including a pump provided around the placement table and configured to control an exhaust amount of the processing gas; a plurality of sensors configured to detect a pressure at a plurality of positions distributed within the processing container; and a controller configured to control an exhaust amount of the plurality of exhaust mechanisms based on a result of a pressure detection by the plurality of sensors so as to suppress unevenness in the pressure of the processing gas supplied to the workpiece.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view illustrating an example of a schematic configuration of a plasma etching apparatus according to a first embodiment.

FIG. 2 is a plan view illustrating an example of an arrangement of exhaust mechanisms according to the first embodiment.

FIG. 3 is a view schematically illustrating an example of flows of exhaust gas to exhaust mechanisms according to the first embodiment.

FIG. 4 is a view illustrating an example of flows of exhaust gas of respective exhaust mechanisms.

FIG. 5A is a plan view illustrating an example of an arrangement of an exhaust mechanism of a comparative example.

FIG. 5B is a graph representing an example of a change in pressure around the placement table in the arrangement of the exhaust mechanism of the comparative example.

FIG. 6A is a plan view illustrating an example of the arrangement of the exhaust mechanisms of an embodiment.

FIG. 6B is a graph representing an example of a change in pressure around the placement table in the arrangement of the exhaust mechanisms of the embodiment.

FIG. 7 is a flowchart illustrating an example of a flow of exhaust control according to the first embodiment.

FIG. 8 is a cross-sectional view illustrating an example of a schematic configuration of a plasma etching apparatus according to a second embodiment.

FIG. 9 is a flowchart illustrating an example of a flow of exhaust control according to the second embodiment.

FIG. 10A is a view illustrating an example of an exhaust amount control of exhaust mechanisms.

FIG. 10B is a view illustrating an example of an exhaust amount control of exhaust mechanisms.

FIG. 11A is a view illustrating an example of an exhaust amount control of exhaust mechanisms.

FIG. 11B is a view illustrating an example of an exhaust amount control of exhaust mechanisms.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

Hereinafter, embodiments of a vacuum processing apparatus and an exhaust control method disclosed herein will be described in detail with reference to the drawings. The vacuum processing apparatus and the exhaust control method disclosed herein are not limited by the embodiments. In addition, respective embodiments may be appropriately combined within a range not inconsistent with processing contents. Hereinafter, an embodiment will be described using a plasma etching apparatus as an example of a vacuum processing apparatus.

However, as described above, in a vacuum processing apparatus, exhaust mechanisms which evacuate the interior of the processing chamber may be arranged unevenly. For example, in the etching processing, in order to generate plasma, radio-frequency power is supplied to a placement table on which a substrate is placed. Therefore, in the plasma etching apparatus, components such as, for example, a radio-frequency power supply, are disposed under the placement table, and exhaust mechanisms are arranged unevenly around the placement table.

However, in the vacuum processing apparatus, when exhaust is performed by the exhaust mechanisms which are arranged unevenly, unevenness may be caused in pressure in the processing chamber, thereby causing unevenness in the processing on a workpiece.

Therefore, it is expected to suppress unevenness in a processing on a workpiece.

### First Embodiment

[Configuration of Plasma Etching Apparatus]

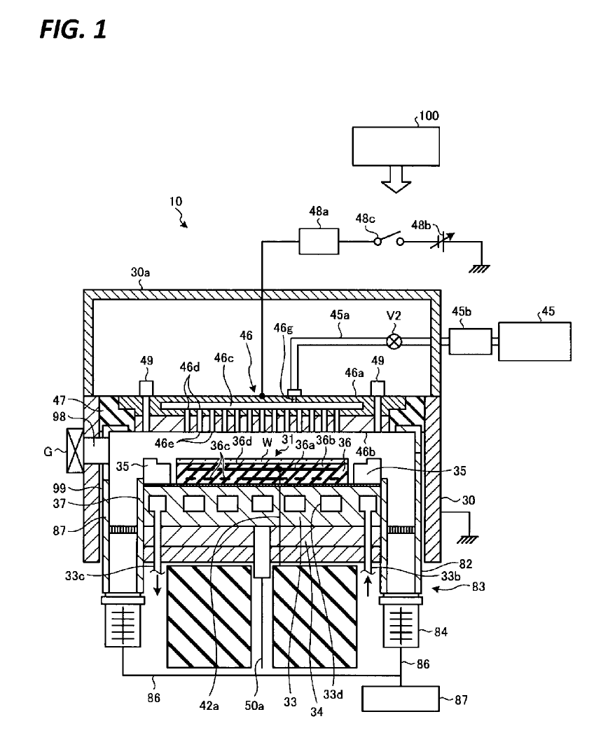

The configuration of a plasma etching apparatus 10 according to a first embodiment will be described. FIG. 1 is a cross-sectional view illustrating an example of a schematic configuration of a plasma etching apparatus according to a first embodiment. The plasma etching apparatus 10 includes a processing container 30 which is airtightly constituted and has an electrically ground potential. The processing container 30 has a cylindrical shape, and is made of, for example, aluminum having an anodized film formed on the surface thereof. The processing container 30 defines a processing space in which plasma is generated. A placement table 31 configured to horizontally support a wafer W thereon is arranged inside the processing container 30.

The placement table 31 has a substantially columnar shape with its bottom faces oriented in a vertical direction, and the upper bottom face serves as a placement surface 36d. The placement table 31 is disposed coaxially with the axis of the cylindrical processing container 30. The placement surface 36d of the placement table 31 has a size larger than that of the wafer W. The placement table 31 includes a base 33 and an electrostatic chuck 36.

The base 33 is made of a conductive metal such as, for example, aluminum. The base 33 functions as a lower electrode. The base 33 is supported by a support base 34 of an insulator. The support base 34 is installed on the bottom of the processing container 30.

The upper surface of the electrostatic chuck 36 has a flat disc shape so as to form a placement surface 36d on which a wafer W is placed. The electrostatic chuck 36 is provided in the center of the placement table 31 in plan view. The electrostatic chuck 36 has an electrode 36a and an insulator 36b. The electrode 36a is provided inside the insulator 36b, and a direct current (DC) power supply (not illustrated) is connected to the electrode 36a via a wire 42a such that a DC voltage is applied from the DC power supply, thereby attracting the wafer W by a Coulomb force. Further, in the electrostatic chuck 36, a heater 36c is provided inside the insulator 36b. Electric power is supplied to the heater 36c via a power supply mechanism to be described later to control the temperature of the wafer W.

In addition, a focus ring 35 made of, for example, single crystal silicon is provided on the outer peripheral edge of the upper face of the placement table 31. Further, a cylindrical inner wall member 37 made of, for example, quartz is provided so as to surround the placement table 31 and the support base 34.

A power supply rod 50 is connected to the base 33. The power supply rod 50 is connected to RF-related components such as, for example, a matching device and an RF power supply, via a wire 50a. The RF-related components are arranged under the placement table 31. In FIG. 1, the arrangement positions where the RF-related components are arranged under the placement table 31 are arranged are indicated by hatched rectangular regions. Radio-frequency power having a predetermined frequency for plasma generation and radio-frequency power having a predetermined frequency for ion drawing-in (for bias) which is lower than that for plasma generation are supplied to the base 33 via the power supply rod 50 and the wire 50a to the RF-related components.

A coolant flow path 33d is formed inside the base 33. A coolant inlet pipe 33b is connected to one end of the coolant flow path 33d, and a coolant outlet pipe 33c is connected to the other end. The plasma etching apparatus 10 is configured to be able to control the temperature of the placement table 31 by circulating a coolant such as, for example, cooling water, in the coolant flow path 33d. In addition, the plasma etching apparatus 10 may be configured such that a coolant flow path is separately provided in the base 33, corresponding to the regions where the wafer W and the focus ring 35 are placed, respectively, so that the temperature of the wafer W and the temperature of the focus ring 35 are individually controllable. The plasma etching apparatus 10 may be configured such that the temperature of the wafer W and the temperature of the focus ring 35 are individually controllable by supplying a cold heat transfer gas to the rear surface side of the wafer W or the focus ring 35. For example, a gas supply pipe for supplying a cold heat transfer gas (backside gas) such as, for example, helium gas, may be provided on the rear surface of the wafer W so as to penetrate, for example, the placement table 31. The gas supply pipe is connected to a gas supply source. With these configurations, the wafer W adsorbed and held by the electrostatic chuck 36 on the upper surface of the placement table 31 is controlled to have a predetermined temperature.

Meanwhile, above the placement table 31, a shower head 46 having a function as an upper electrode is provided so as to face the placement table 31 in parallel. The shower head 46 and the placement table 31 function as a pair of electrodes (an upper electrode and a lower electrode). In the present embodiment, the shower head 46 corresponds to a supply unit configured to supply a processing gas.

The shower head 46 is provided on the ceiling wall portion of the processing container 30. The shower head 46 includes a main body 46a and a top plate 46b forming an electrode plate, and is supported on the upper portion of the processing container 30 via an insulating member 47. The main body 46a is made of a conductive material, for example, aluminum having an anodic oxide film formed on the surface thereof, and is configured to detachably support the top plate 46b under the main body 46a.

A gas diffusion chamber 46c is provided in the vicinity of the center of the main body 46a and a large number of gas flow holes 46d are formed in the bottom portion of the main body 46a so as to be located under the gas diffusion chamber 46c. Gas introduction holes 46e are provided in the top plate 46b so as to penetrate the upper top plate 46b in the thickness direction so as to overlap the gas flow holes 46d of the main body 46a. With this configuration, the processing gas supplied to the gas diffusion chamber 46c is diffused and supplied in a shower form into the processing container 30 via the gas flow holes 46d and the gas introduction holes 46e.

A gas introduction port 46g is formed in the main body portion 46a so as to introduce the processing gas into the gas diffusion chamber 46c. One end of a gas supply pipe 45a is connected to the gas introduction port 46g. A processing gas supply source 45 is connected to the other end of the gas supply pipe 45a so as to supply the processing gas. In the gas supply pipe 45a, a mass flow controller (MFC) 45b and an opening/closing valve V2 are installed in this order from the upstream side. Then, a processing gas for plasma etching is supplied from the processing gas supply source 45 to the gas diffusion chamber 46c via the gas supply pipe 45a, and from the gas diffusion chamber 46c, the processing gas is diffused and supplied in a shower form into the processing container 30 through the gas flow holes 46d and the gas introduction holes 46e.

A variable DC power source 48b is electrically connected to the shower head 46 via a low-pass filter (LPF) 48a. The variable DC power source 48b is configured to be capable of turning on/off power feeding by an on/off switch 48c. The current/voltage of the variable DC power supply 48b and the on/off of the on/off switch 48c are controlled by the controller 100 to be described later. When plasma is generated in the processing space, the on/off switch 48c is turned on by the controller 100 as necessary, and a predetermined DC voltage is applied to the shower head 46 serving as the upper electrode.

In the shower head 46, a plurality of pressure detection sensors 49 are dispersed and provided on the lower surface thereof opposite the placement table 31. In the shower head 46 according to the present embodiment, a plurality of sensors 49 are provided so as to surround a region of the lower surface of the shower head 46 where the gas flow holes 46d and the gas introduction holes 46e are formed. Each sensor 49 is disposed such that a pressure detection region thereof is exposed on the lower surface of the shower head 46, and outputs the information on the detected pressure to the control section 100 to be described later via a wire (not illustrated). The controller 100 detects pressure at a plurality of dispersed positions in the processing container 30 using each sensor 49.

In the upper portion of the processing container 30, a cylindrical ground conductor 30a is provided so as to extend from the sidewall of the processing container 30 to a position higher than the height position of the shower head 46. The cylindrical ground conductor 30a has a ceiling wall on the top thereof.

In the bottom of the processing container 30, a plurality of exhaust mechanisms 83 are provided around the placement table 31. Each of the exhaust mechanisms 83 according to the present embodiment has a vacuum pump 84. As an example of the vacuum pump 84, for example, a turbo molecular pump may be mentioned. One end of an exhaust pipe 86 is connected to the exhaust side of the vacuum pump 84 of each exhaust mechanism 83. The other end of each exhaust pipe 86 is connected to one dry pump 87. Each of the exhaust mechanisms 83 is capable of reducing the pressure in the processing container 30 to a predetermined vacuum degree by operating the vacuum pump 84 and the dry pump 87. The processing gas supplied into the processing container 30 from the shower head 46 flows to the respective exhaust mechanisms 83 and is exhausted as indicated by arrows.

Meanwhile, a gate 98 used for loading/unloading a wafer W is provided in the side wall inside the processing container 30. A gate valve G is provided in the gate 98 so as to open/close the gate 98. The gate 98 is connected to a vacuum transport chamber (not illustrated) via a gate valve G while keeping the airtightness, so that a wafer W can be loaded/unloaded from/into the vacuum transport chamber while maintaining the vacuum atmosphere in the vacuum transport chamber.

On the inside of the side portion of the processing container 30, a deposit shield 99 is provided along the inner wall surface. The deposit shield 99 suppresses etching byproduct (deposit) from adhering to the processing container 30. The deposit shield 99 is configured to be detachable.

The operation of the plasma etching apparatus 10 having the above configuration is totally controlled by the controller 100. The controller 100 is, for example, a computer, and includes storage units such as, for example, a central processing unit (CPU), a random-access memory (RAM), a read only memory (ROM), and an auxiliary storage device. The CPU operates based on a program or a recipe stored in the storage unit, and controls the operation of the entire apparatus. For example, the CPU controls the operation of a plasma processing such as, for example, an etching processing. The controller 100 may be provided inside or outside the plasma etching apparatus 10. In the case where the controller 100 is provided outside the plasma etching apparatus 10, the controller 100 is capable of controlling the plasma etching apparatus 10 through a wired or wireless communication unit.

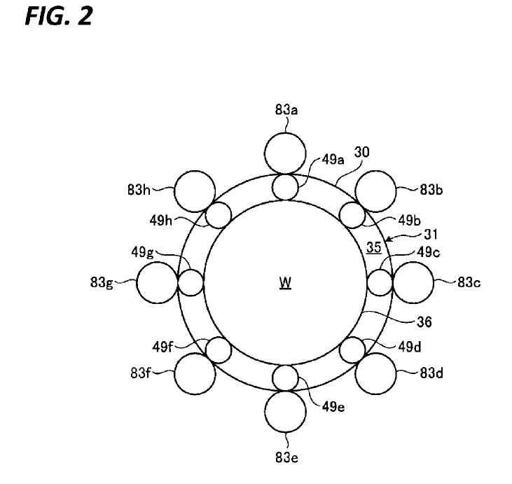

Next, the arrangement of the exhaust mechanisms 83 according to the present embodiment will be described. FIG. 2 is a plan view illustrating an example of an arrangement of exhaust mechanisms according to the first embodiment. FIG. 2 illustrates a plan view of the placement table 31 disposed inside the cylindrical processing container 30, in which the placement table 31 is viewed from above. Around the placement table 31, a plurality of exhaust mechanisms 83 are arranged at regular intervals. In the example of FIG. 2, eight exhaust mechanisms 83a to 83h are arranged around the placement table 31 at an interval of 45°. In addition, in FIG. 2, the arrangement positions of the plurality of sensors 49 are illustrated. In the example of FIG. 2, eight sensors 49a to 49h are arranged at an interval of 45° corresponding to the arrangement positions of the exhaust mechanisms 83a to 83h. In this embodiment, the sensors 49a to 49h are respectively disposed at positions on the paths reaching the respective ones of the exhaust mechanisms 83a to 83h from the center of the placement table 31 such that the exhaust mechanisms 83 and the sensors 49 are associated with each other in one-to-one correspondence. For example, the exhaust mechanism 83a and the sensor 49a correspond to each other.

The number of the exhaust mechanism 83 and the sensor 49 is not limited to eight. The number of the exhaust mechanism 83 and the sensor 49 may be two or more, and may be three or more. Further, it is not necessary that the number of the sensors 49 is equal to the number of the exhaust mechanisms 83, and the number of the sensors 49 may be different from the number of the exhaust mechanisms 83.

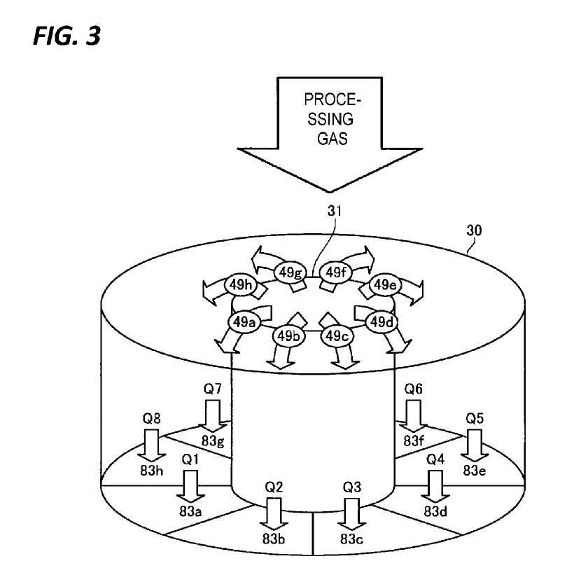

FIG. 3 is a view schematically illustrating an example of flows of exhaust gas to exhaust mechanisms according to the first embodiment. The processing gas supplied from the shower head 46 is exhausted by the exhaust mechanisms 83a to 83h disposed around the placement table 31. In addition, the sensors 49a to 49h detect the pressures in the processing space on the placement table 31 when the processing gas flows to each of the exhaust mechanisms 83a to 83h. In FIG. 3, the exhaust amounts by the exhaust mechanisms 83a to 83h are indicated as Q₁ to Q₈.

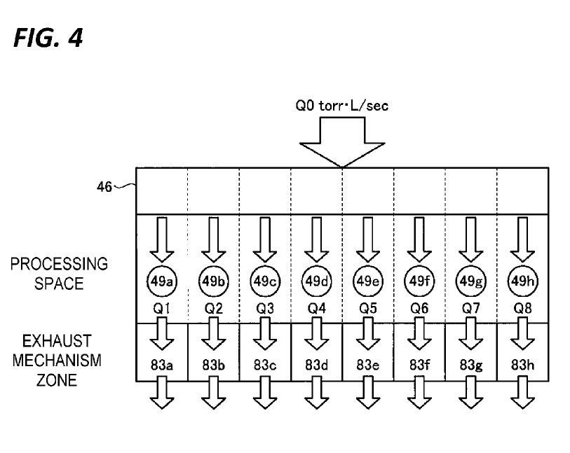

FIG. 4 is a view illustrating an example of flows of exhaust gas of respective exhaust mechanisms. FIG. 4 illustrates the flows of exhaust gas to the exhaust mechanisms 83a to 83h disposed around the placement table 31 in a plan view. For example, the processing gas is supplied from the shower head 46 at a flow rate of Q₀ [Torr·L/sec]. When the pressure in the processing container 30 is constant, the relationship of the following equation (1) is established between the flow rate Q₀ and the exhaust amounts Q₁ to Q₈ by the exhaust mechanisms 83a to 83h.

Q₀=Q₁+Q₂+Q₃+Q₄+Q₅+Q₆+Q₇+Q₈ (1)

Return to FIG. 1. The controller 100 controls each unit of the plasma etching apparatus 10. For example, in the case of performing a plasma processing such as, for example, an etching processing, on the wafer W, the controller 100 controls the processing gas supply source 45, the mass flow controller 45b, and the on/off valve V2 so as to supply various processing gases used for the etching processing from the shower head 46 into the processing container 30. Further, the controller 100 causes the on/off switch 48c to be turned on so as to apply a predetermined DC voltage to the shower head 46. In addition, the controller 100 controls the RF-related components so as to supply RF power for plasma generation and ion drawing-in from the RF power supply to the placement table 31. As a result, plasma is generated in the processing space between the shower head 46 and the placement table 31.

In the case of performing a plasma processing such as, for example, an etching processing, on a wafer W, the controller 100 operates the vacuum pump 84 and the dry pump 87 of each exhaust mechanism 83 to exhaust the processing gas, thereby achieving a predetermined vacuum degree, Perform exhaust. For example, the controller 100 adjusts the overall pressure in the processing container 30 by interlockingly increasing and decreasing the rotation speeds of the vacuum pumps 84 of respective exhaust mechanisms 83 in the same ratio.

In addition, when the pressure sensed by each sensor 49 approaches the target vacuum degree, the controller 100 controls the rotation speed of the vacuum pump 84 of each exhaust mechanism 83 based on the detection result of the pressure by each sensor 49 so as to suppress unevenness in the pressure of the processing gas supplied from the shower head 46. For example, when a detected pressure is higher than the target vacuum degree by a predetermined allow value or more, the controller 100 performs control to increase the rotation speed of the vacuum pump 84 of the exhaust mechanism 83 corresponding to the sensor 49 in which the pressure higher by the allowable value or more is detected. In addition, when a detected pressure is lower than the target vacuum degree by a predetermined allowable value or more, the controller 100 performs control to decrease the rotation speed of the vacuum pump 84 of the exhaust mechanism 83 corresponding to the sensor 49 in which the pressure lower by the allowable value or more is detected.

In addition, the controller 100 controls the rotation speed of the vacuum pump 84 of each exhaust mechanism 83 such that a difference between the pressures detected by respective sensors 49 becomes small. For example, when the pressure difference between the highest pressure and the lowest pressure among the pressures detected by the respective sensors 49 is equal to or larger than the predetermined allowable value, the controller 100 performs control to increase the rotation speed of the vacuum pump 84 of the exhaust mechanism 83 corresponding to the sensor 49 in which the highest pressure is detected, or to decrease the rotation speed of the vacuum pump 84 of the exhaust mechanism 83 corresponding to the sensor 49 in which the lowest pressure is detected. Each allowable value is appropriately determined depending on the conditions of the plasma processing to be performed.

As a result, in the plasma etching apparatus 10, unevenness in the pressure of the processing gas in the processing space is suppressed, and thus it is possible to suppress occurrence of unevenness in an etching processing on a wafer W.

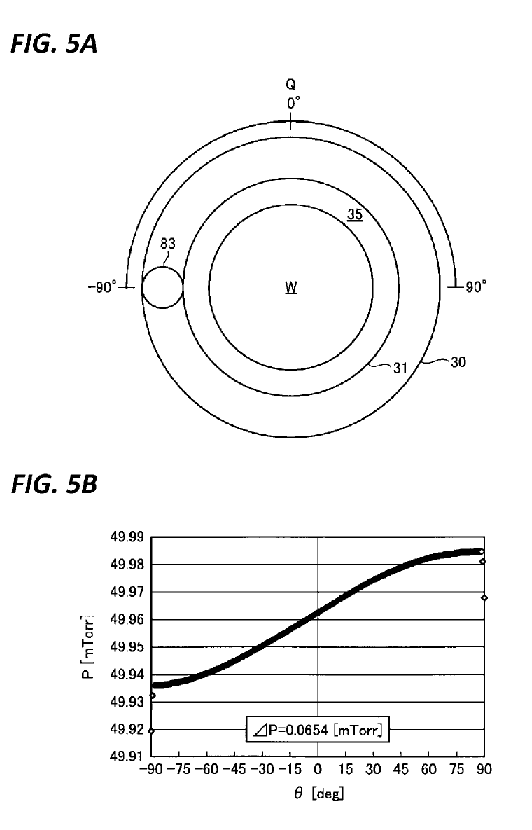

Here, an example of unevenness in pressure will be described. For example, as a comparative example, it is assumed that, in the plasma etching apparatus 10, the processing gas is exhausted by one exhaust mechanism 83. FIG. 5A is a plan view illustrating an example of an arrangement of an exhaust mechanism of a comparative example. In the example of FIG. 5A, the position around the placement table 31 is indicated by an angle θ where the position of the exhaust mechanism 83 is −90° and the position on the opposite side of the exhaust mechanism 83 is 90°. In the comparative example, one exhaust mechanism 83 is disposed at the position of −90°.

As described above, in the plasma etching apparatus 10, RF-related components such as, for example, an RF power supply, are disposed under the placement table 31. Therefore, as illustrated in FIG. 5A, in the plasma etching apparatus 10, the exhaust mechanism 83 is arranged unevenly around the placement table 31. In this case, in the plasma etching apparatus 10, unevenness occurs in the pressure of the processing gas in the processing space during the etching processing. FIG. 5B is a graph representing an example of a change in pressure around the placement table in the arrangement of the exhaust mechanism of the comparative example. FIG. 5B represents the change in pressure around the placement table 31 at the angle θ illustrated in FIG. 5A. As represented in FIG. 5B, a pressure difference of 0.0654 mTorr occurs at the positions of 90° and a position of −90°.

In the plasma etching apparatus 10, when unevenness occurs in the pressure of the processing gas in this way, unevenness may occur in the etching processing on the wafer W.

Meanwhile, in the plasma etching apparatus 10 according to the present embodiment, since it is possible to suppress unevenness in the pressure of the processing gas in the processing space, it is possible to suppress occurrence of unevenness in the etching processing on the wafer W.

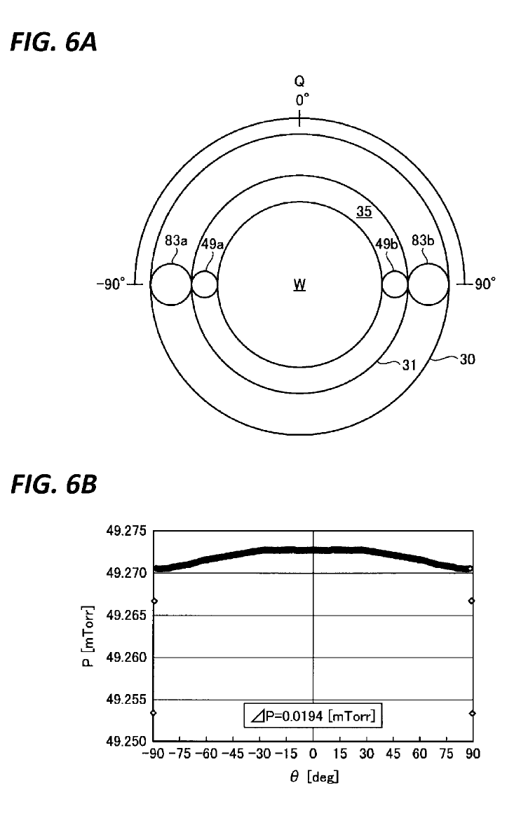

Here, as an example, a case where the plasma etching apparatus 10 according to the present embodiment is configured to evacuate the processing gas using two exhaust mechanisms 83 will be described. FIG. 6A is a plan view illustrating an example of the arrangement of the exhaust mechanisms of an embodiment. In the example of FIG. 6A, the exhaust mechanism 83a and the sensor 49a are disposed at the position of −90° around the placement table 31, and the exhaust mechanism 83b and the sensor 49b are disposed at the position of 90°. The controller 100 controls the exhaust amounts of the exhaust mechanisms 83a and 83b based on the pressure detection results of the sensors 49a and 49b so as to suppress unevenness in the pressure of the processing gas supplied from the shower head 46. FIG. 6B is a graph representing an example of a change in pressure around the placement table in the arrangement of the exhaust mechanisms of the example. In the example of FIG. 6B, the pressure difference between the 90° position and the −90° position is reduced to 0.0194 mTorr.

[Flow of Exhaust Control]

Next, a flow of exhaust control performed by the plasma etching apparatus 10 according to the first embodiment will be described.

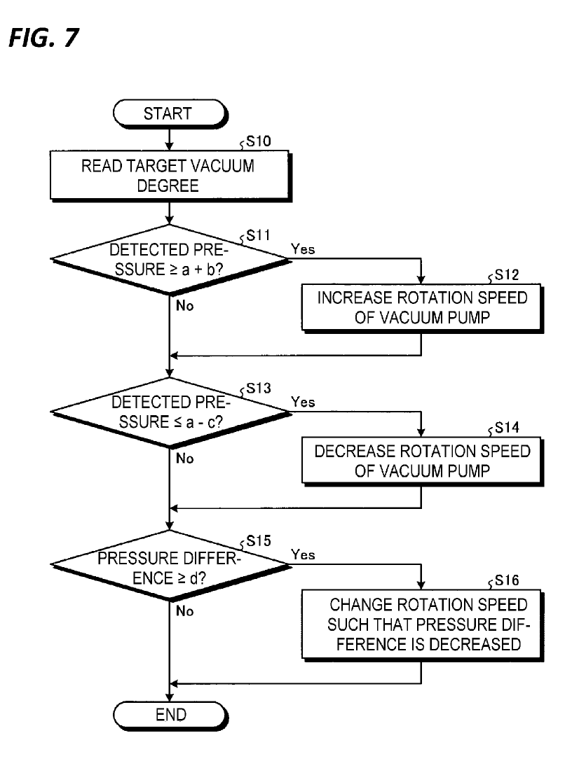

The controller 100 detects the pressure by respective sensors 49 at a predetermined cycle. Every time the pressure is detected, the controller 100 performs the following exhaust control processing. FIG. 7 is a flowchart illustrating an example of a flow of exhaust control according to the first embodiment.

The controller 100 reads the target vacuum degree (step S10). Here, it is assumed that the target vacuum is a [Pa].

The controller 100 determines whether or not the pressure detected by each sensor 49 is equal to or higher than the target vacuum degree a plus (+) an allowable value b (step S11). When a pressure equal to or higher than the target vacuum degree a +the allowable value b is detected, the controller 100 increases the rotation speed of the vacuum pump 84 of the exhaust mechanism 83 corresponding to the sensor 49 in which the pressure equal to or higher than the target vacuum degree a +the allowable value b is detected (step S12).

In addition, the controller 100 determines whether or not the pressure detected by each sensor 49 is equal to or lower than the target vacuum degree a minus (−) an allowable value c (step S13). When a pressure equal to or lower than the target vacuum degree a −the allowable value c is detected, the controller 100 decreases the rotation speed of the vacuum pump 84 of the exhaust mechanism 83 corresponding to the sensor 49 in which the pressure equal to or lower than the target vacuum degree a −the allowable value c is detected (step S14).

In addition, the controller 100 determines whether or not the pressure difference between the highest pressure and the lowest pressure among the pressures detected by the respective sensors 49 is equal to or higher than an allowable value d (step S15). When a pressure equal to or lower than the target vacuum degree a −the allowable value c is detected, the controller 100 controls the rotation speed of the vacuum pump 84 of each exhaust mechanism 83 such that the pressure difference between the pressures detected by respective sensors 49 is decreased (step S16). For example, the controller 100 performs increases the rotation speed of the vacuum pump 84 of the exhaust mechanism 83 corresponding to the sensor 49 in which the highest pressure is detected, or decreases the rotation speed of the vacuum pump 84 of the exhaust mechanism 83 corresponding to the sensor 49 in which the lowest pressure is detected.

As described above, the plasma etching apparatus 10 according to the present embodiment includes a processing container 30, a plurality of exhaust mechanisms 83, a plurality of sensors 49, and a controller 100. The processing container 30 includes therein a placement table 31 configured to place a wafer W as a workpiece thereon and a shower head 46 configured to supply a processing gas. The plurality of exhaust mechanisms 83 are configured to control an exhaust amount for exhausting the processing gas, and arranged around the placement table 31. The plurality of sensors 49 detect pressures at a plurality of dispersed positions in the processing container 30. The controller 100 controls the exhaust amounts of the plurality of exhaust mechanisms 83 based on the pressure detection results of the plurality of sensors 49 so as to suppress unevenness in the pressure of the processing gas supplied to a wafer W. As a result, in the plasma etching apparatus 10, since it is possible to suppress unevenness in the pressure of the processing gas in the processing space, it is possible to suppress occurrence of unevenness in the etching processing on the wafer W.

In addition, in the plasma etching apparatus 10 according to the present embodiment, a plurality of exhaust mechanisms 83 are arranged around the mounting placement table 31 at regular intervals. The plurality of sensors 49 are arranged in the shower head 46 to correspond to the arrangement positions of the plurality of exhaust mechanisms 83. As a result, in the plasma etching apparatus 10, since it is possible to evenly control exhaust in the circumferential direction of the placement table 31, it is possible to suppress unevenness in the pressure of the processing gas.

Further, in the plasma etching apparatus 10 according to the present embodiment, each exhaust mechanism 83 has a vacuum pump 84 capable of controlling the exhaust amount. The controller 100 controls the exhaust amounts of the vacuum pumps 84. Thus, in the plasma etching apparatus 10, it is possible to control the exhaust amounts of the exhaust mechanisms 83 by controlling the rotation speeds of the vacuum pumps 84.

Further, in the plasma etching apparatus 10 according to the present embodiment, the processing container 30 has a cylindrical shape. The placement table 31 has a columnar shape and is disposed coaxially with the axis of the processing container 30. The shower head 46 is arranged to face the placement table 31. As a result, the plasma etching apparatus 10 is capable of performing etching with high uniformity on a wafer W.

### Second Embodiment

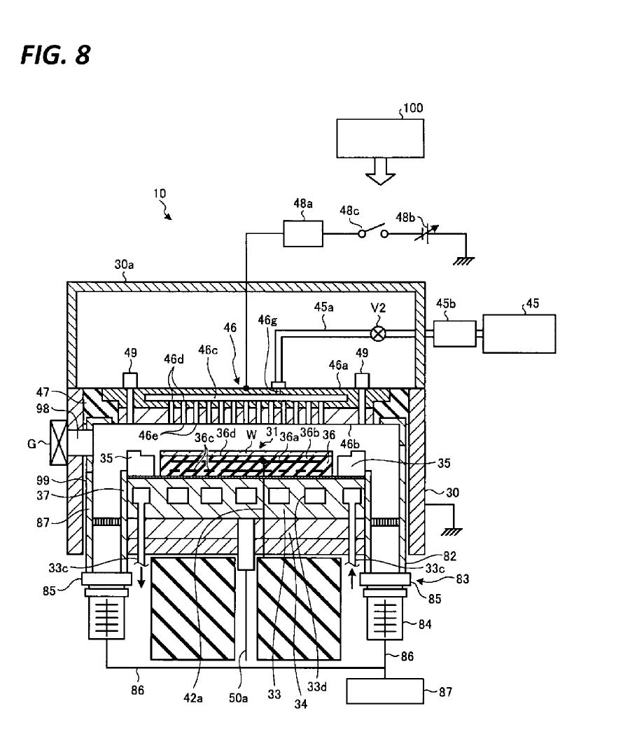

Next, a second embodiment will be described. FIG. 8 is a cross-sectional view illustrating an example of a schematic configuration of a plasma etching apparatus according to a second embodiment. Since the schematic configuration of the plasma etching apparatus 10 according to the second embodiment is partly the same as that of the plasma etching apparatus 10 according to the first embodiment illustrated in FIG. 1, the same parts will be denoted by the same reference numerals and different points will be mainly described.

An exhaust mechanism 83 according to the second embodiment has a vacuum pump 84 and a valve 85 disposed in the intake port of the vacuum pump 84 so as to change the opening/closing amount of the intake port. As an example of the valve 85, for example, a butterfly valve may be mentioned. The exhaust mechanism 83 according to the second embodiment is configured to be able to control the exhaust amount by changing the opening/closing amount of the valve 85.

In the case of performing a plasma processing such as, for example, an etching processing, on a wafer W, the controller 100 operates the vacuum pump 84 and the dry pump 87 of each exhaust mechanism 83 to exhaust the processing gas, thereby achieving a predetermined vacuum degree, Perform exhaust. For example, the controller 100 adjusts the overall pressure in the processing container 30 by interlockingly increasing and decreasing the opening/closing amounts of the valves 85 of respective exhaust mechanisms 83 in the same ratio.

In addition, when the pressure sensed by each sensor 49 approaches the target vacuum degree, the controller 100 controls the opening/closing amount speed of the valve 85 of each exhaust mechanism 83 based on the pressure detection result of each sensor 49 so as to suppress unevenness in the pressure of the processing gas supplied from the shower head 46. For example, when a detected pressure is higher than the target vacuum degree by a predetermined allow value or more, the controller 100 performs control to increase the opening/closing amount of the valve 85 of the exhaust mechanism 83 corresponding to the sensor 49 in which the pressure higher by the allowable value or more is detected. In addition, when a detected pressure is lower than the target vacuum degree by a predetermined allowable value or more, the controller 100 performs control to decrease the opening/closing amount of the valve 85 of the exhaust mechanism 83 corresponding to the sensor 49 in which the pressure lower by the allowable value or more is detected. In addition, the controller 100 controls the opening/closing amount of the valve 85 of each exhaust mechanism 83 such that a difference between the pressures detected by respective sensors 49 becomes small. For example, when the pressure difference between the highest pressure and the lowest pressure among the pressures detected by the respective sensors 49 is equal to or larger than the predetermined allowable value, the controller 100 performs control to increase the opening/closing amount of the valve 85 of the exhaust mechanism 83 corresponding to the sensor 49 in which the highest pressure is detected, or to decrease the opening/closing amount of the valve 85 of the exhaust mechanism 83 corresponding to the sensor 49 in which the lowest pressure is detected. Each allowable value is appropriately determined depending on the conditions of the plasma processing to be performed.

As a result, in the plasma etching apparatus 10, the unevenness in the pressure of the processing gas in the processing space is suppressed, and thus it is possible to suppress occurrence of unevenness in an etching processing on a wafer W.

[Flow of Exhaust Control]

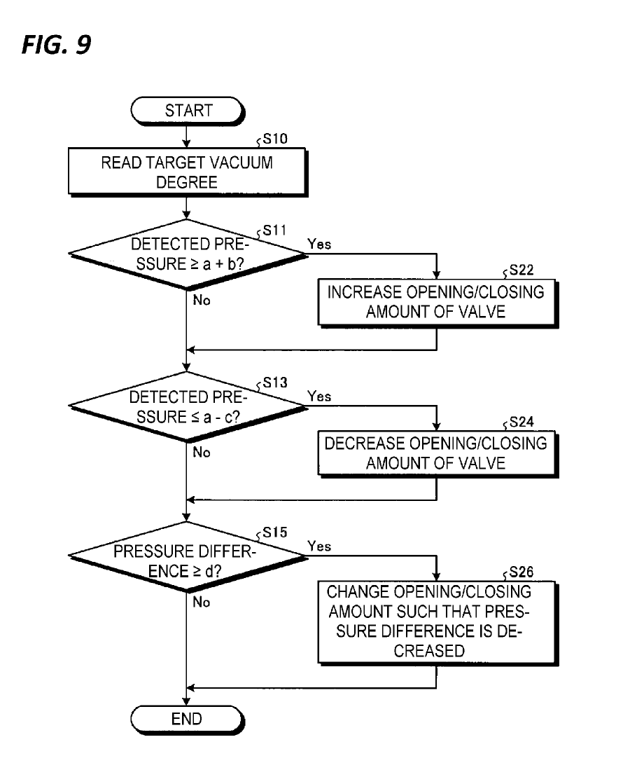

Next, a flow of exhaust control performed by the plasma etching apparatus 10 according to the second embodiment will be described. FIG. 9 is a flowchart illustrating an example of a flow of exhaust control according to the second embodiment. Since the exhaust control according to the second embodiment illustrated in FIG. 9 is partly the same as the exhaust control according to the first embodiment illustrated in FIG. 7, the same parts will be denoted by the same reference numerals, and different points will be mainly described.

When a pressure equal to or higher than the target vacuum degree a plus (+) the allowable value b is detected, the controller 100 increases the opening/closing amount of the valve 85 of the exhaust mechanism 83 corresponding to the sensor 49 in which the pressure equal to or higher than the target vacuum degree a +the allowable value b is detected (step S22).

In addition, when a pressure equal to or lower than the target vacuum degree a minus (−) the allowable value c is detected, the controller 100 decreases the opening/closing amount of the valve 85 of the exhaust mechanism 83 corresponding to the sensor 49 in which the pressure equal to or lower than the target vacuum degree a −the allowable value c is detected (step S24).

Further, when a pressure equal to or lower than the target vacuum degree a −the allowable value c is detected, the controller 100 controls the opening/closing amount of the valve 85 of each exhaust mechanism 83 such that the pressure difference between the pressures detected by respective sensors 49 is decreased (step S26). For example, the controller 100 performs increases the opening/closing amount of the valve 85 of the exhaust mechanism 83 corresponding to the sensor 49 in which the highest pressure is detected, or decreases the opening/closing amount of the valve 85 of the exhaust mechanism 83 corresponding to the sensor 49 in which the lowest pressure is detected.

As a result, in the plasma etching apparatus 10, since the unevenness in the pressure of the processing gas in the processing space is suppressed, it is possible to suppress occurrence of unevenness in an etching processing on a wafer W.

As described above, in the plasma etching apparatus 10 according to the present embodiment, each exhaust mechanism 83 has a vacuum pump 84 and a valve 85 disposed in the intake port of the vacuum pump 84 so as to change the opening/closing amount of the intake port. The controller 100 controls the opening/closing amount of the vacuum pump 85. Thus, in the plasma etching apparatus 10, it is possible to control the exhaust amounts of the exhaust mechanisms 83 by controlling the opening/closing amounts of the valves 85.

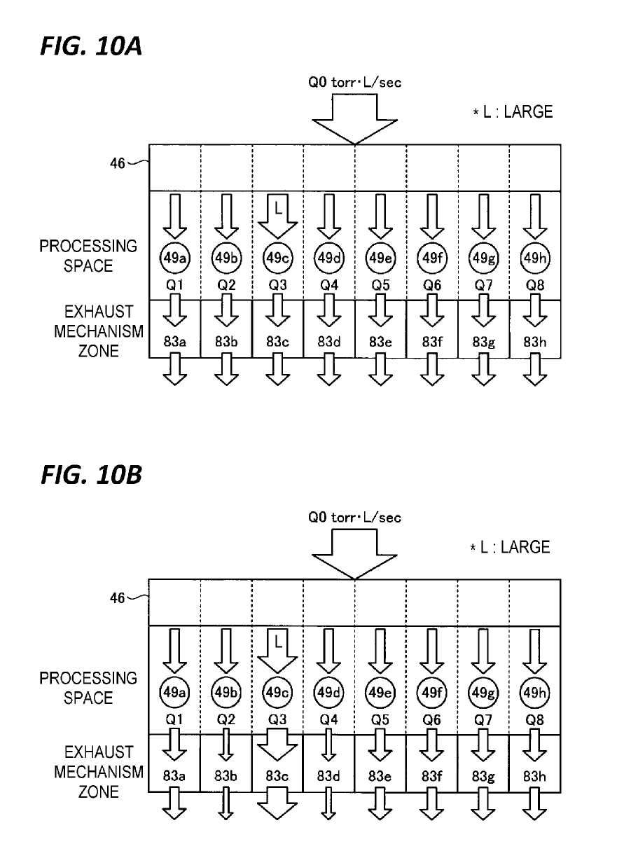

For example, the controller 100 has been described with reference to a case in which the exhaust amount of the exhaust mechanism 83 corresponding to a sensor 49, of which the detected pressure is higher than that of the other sensors 49, is increased, as an example. However, when the exhaust amount of the exhaust mechanism 83 is increased, the peripheral pressure is also decreased. Therefore, for example, the controller 100 may perform control to increase the exhaust amount of the exhaust mechanism 83 corresponding to the sensor 49, of which the detected pressure is higher than that of the other sensors 49, based on the pressure detection result of each sensor 49, and to decrease the exhaust amount of the exhaust mechanisms 83 on both sides of the exhaust mechanism 83 of which the exhaust amount is increased. FIGS. 10A and 10B are views illustrating an example of an exhaust amount control of an exhaust mechanism. As illustrated in FIG. 10A, when the processing gas supplied from the shower head 46 flows in a large amount only in the sensor 49c part in the processing container 30, the pressure of the sensor 49c is increased. When the rotation speed of the vacuum pump 84 of the exhaust mechanism 83c is increased in order to adjust unevenness in the pressure, the exhaust amount Q₃ increases, and thus the pressure of the sensor 49c is decreased. In this case, the space above the exhaust mechanisms 83b and 83d adjacent to the exhaust mechanism 83c is also influenced, and thus the pressure therein becomes low. Therefore, for example, as illustrated in FIG. 10B, when a high pressure is detected by the sensor 49c, the controller 100 may perform control to increase the exhaust amount of the exhaust mechanism 83c, and to decrease the exhaust amounts of the exhaust mechanisms 83b and 83d on the both sides of the exhaust mechanism 83c. As a result, in the plasma etching apparatus 10, since unevenness in the pressure of the processing gas in the processing space is suppressed, it is possible to suppress occurrence of unevenness in an etching processing on a wafer W.

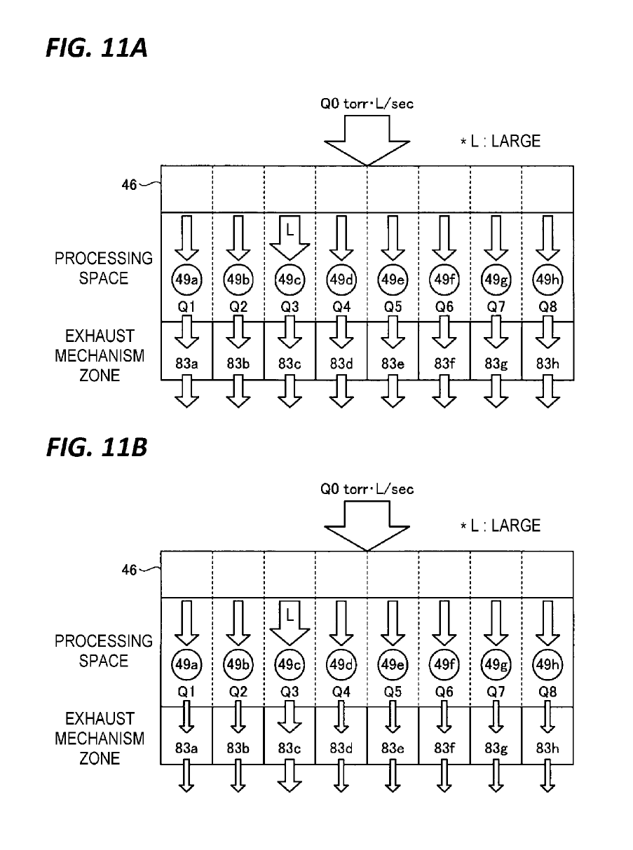

Further, the exhaust mechanisms 83 have a limitation on the rotation speed of the vacuum pumps 84, and there is a limit in the exhaust amount. Therefore, there is an upper limit in the control range of the exhaust mechanisms 83, such as setting 90% of the rotation speed of the vacuum pumps 84 as the upper limit. Therefore, when the exhaust amount of the exhaust mechanism 83 corresponding to the sensor 49 of which the detected pressure is higher than that of the other sensors 49 is the upper limit of control, the controller 100 may perform control to decrease the exhaust amount of all the other exhaust mechanisms 83, except for the corresponding exhaust mechanism 83. FIGS. 11A and 11B are views illustrating an example of an exhaust amount control of exhaust mechanisms. As illustrated in FIG. 11A, when the processing gas supplied from the shower head 46 flows in a large amount only in the sensor 49c part in the processing container 30, the pressure of the sensor 49c is increased. In order to adjust unevenness in the pressure, it is desired to increase the rotation speed of the vacuum pump 84 of the exhaust mechanism 83c. However, when the rotation speed of the vacuum pump 84 is close to the upper limit, the exhaust amount of the exhaust mechanism 83c may not be increased. Therefore, for example, as illustrated in FIG. 11B, when a high pressure is detected by the sensor 49c and the exhaust amount of the exhaust mechanism 83c is the upper limit of the control, the controller 100 may perform a control to decrease the exhaust amounts of the exhaust mechanisms 83a, 83b, 83d to 83h, except for the exhaust mechanism 83c. As a result, in the plasma etching apparatus 10, since unevenness in the pressure of the processing gas in the processing space is suppressed, it is possible to suppress occurrence of unevenness in an etching processing on a wafer W.

In the embodiments, the case where the processing container 30 is cylindrical and the columnar placement table 31 is disposed in the processing container 30 has been described as an example, but the present disclosure is not limited thereto. The processing container 30 and the placement table 31 may have a polygonal shape such as, for example, a rectangular shape.

In the embodiments, the case where the workpiece is a wafer W has been described as an example, but the present disclosure is not limited thereto. Any workpiece may be used as long as the workpiece is disposed in the vacuum processing container and processed using a processing gas. For example, the workpiece may be a glass substrate.

In the embodiments, the case where a processing gas is supplied to a wafer W placed on the placement table 31 from the upper side of the placement table 31 from the shower head 46 has been described as an example, but the present disclosure is not limited thereto. A plurality of supply units configured to supply the processing gas may be provided around the placement table 31 in the processing container 30, and the processing gas may be supplied from the lateral side of the placement table 31.

Further, in the embodiments, the plasma etching apparatus 10 is used as the vacuum processing apparatus, but the present disclosure is not limited thereto. The vacuum processing apparatus may be of any type as long as the inside of the processing container is evacuated and a processing using a processing gas is performed therein.

According to the present disclosure, it is possible to suppress unevenness in a processing on a workpiece.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A vacuum processing apparatus comprising:
a processing container including a placement table configured to place a workpiece thereon and a gas supply source configured to supply a processing gas;
a plurality of exhaust mechanisms each including a pump provided around the placement table and configured to control an exhaust amount of the processing gas;
a plurality of sensors configured to detect a pressure at a plurality of positions distributed within the processing container; and
a controller configured to control an exhaust amount of the plurality of exhaust mechanisms based on a result of a pressure detection by the plurality of sensors so as to suppress unevenness in a pressure of the processing gas supplied to the workpiece.

2. The vacuum processing apparatus of claim 1, wherein the plurality of exhaust mechanisms are arranged around the placement table at regular intervals, and
the plurality of sensors are arranged on at least one side of the placement table and the gas supply source to correspond to arrangement positions of the plurality of exhaust mechanisms.

3. The vacuum processing apparatus of claim 2, wherein the controller performs a control to increase the exhaust amount of an exhaust mechanism corresponding to a sensor of which a detected pressure is higher than that of other sensors based on pressure detection results of the plurality of sensors, and to decrease the exhaust amount of exhaust mechanisms on both sides of the exhaust mechanism of which the exhaust amount is increased.

4. The vacuum processing apparatus of claim 2, wherein, when the exhaust amount of the exhaust mechanism corresponding to a sensor of which a detected pressure is higher than that of the other sensors is an upper limit of control, the controller performs a control to decrease the exhaust amount of all other exhaust mechanisms except for the exhaust mechanism.

5. The vacuum processing apparatus claim 1, wherein the controller controls the exhaust amount of the vacuum pump of each of the plurality of exhaust mechanisms.

6. The vacuum processing apparatus claim 1, wherein each of the plurality of exhaust mechanisms includes a valve disposed in an intake port of the vacuum pump to change an opening/closing amount of the intake port, and
the controller controls the opening/closing amount of the valve.

7. The vacuum processing apparatus claim 1, wherein the processing container is formed in a cylindrical shape,
the placement table is formed in a columnar shape and disposed coaxially with an axis of the processing container, and
the gas supply source is disposed to face the placement table.

8. The vacuum processing apparatus of claim 3, wherein, when the exhaust amount of the exhaust mechanism corresponding to a sensor of which a detected pressure is higher than that of the other sensors is an upper limit of control, the controller performs a control to decrease exhaust amounts of all other exhaust mechanisms except for the exhaust mechanism.

9. The vacuum processing apparatus claim 8, wherein the controller controls the exhaust amount of the vacuum pump of each of the plurality of exhaust mechanisms.

10. The vacuum processing apparatus claim 9, wherein each of the plurality of exhaust mechanisms includes a valve disposed in an intake port of the vacuum pump to change an opening/closing amount of the intake port, and
the controller controls the opening/closing amount of the valve.

11. The vacuum processing apparatus claim 10, wherein the processing container is formed in a cylindrical shape,
the placement table is formed in a columnar shape and disposed coaxially with an axis of the processing container, and
the gas supply source is disposed to face the placement table.

12. An exhaust control method comprising:
detecting pressures at a plurality of positions of a processing container by a plurality of sensors distributed within the processing container including therein a placement table configured to place a workpiece thereon and a gas supply source configured to supply a processing gas; and
controlling an exhaust amount of a plurality of exhaust mechanisms configured to control an exhaust amount of a processing gas supplied to the workpiece and provided around the placement table, based on pressure detection results of the plurality of sensors so as to suppress unevenness of a pressure of the processing gas supplied to the workpiece.
